(19) United States
(12) Patent Application Publication
(10) Pub. No.: US 2026/0055291 A1
(43) Pub. Date: Feb. 26, 2026

(54) COMPOSITION FOR TREATING SEMICONDUCTOR DEVICE AND METHOD FOR MANUFACTURING MODIFIED SUBSTRATE

(71) Applicant: FUJIFILM Corporation, Tokyo (JP)

(72) Inventors: Akihiro Hakamata, Shizuoka (JP); Tomonori Takahashi, Shizuoka (JP)

(21) Appl. No.: 19/372,966

(22) Filed: Oct. 29, 2025

Related U.S. Application Data
(63) Continuation of application No. PCT/JP2024/015841, filed on Apr. 23, 2024.

(30) Foreign Application Priority Data
May 16, 2023 (JP) 2023-080666

(51) Int. Cl. C09D 125/06; C09D 7/20; C09D 7/63; H01L 21/02

(52) U.S. Cl. CPC C09D 125/06; C09D 7/20; C09D 7/63; H01L 21/02118; H01L 21/02255; H01L 21/02307

(57) ABSTRACT

The present invention provides a composition for treating a semiconductor device, which can preferentially form a coating film on a first surface in a case of being brought into contact with a substrate having a first surface containing a metal atom and a second surface not containing a metal atom, and can selectively form a coating film on the first surface even after storage; and a method for manufacturing a modified substrate using the composition for treating a semiconductor device. The composition for treating a semiconductor device of the present invention contains a polymer having a functional group which interacts with a surface containing a metal atom in a substrate and an ethylenically unsaturated group, a polymerization inhibitor, and a solvent.

### CROSS-REFERENCE TO RELATED APPLICATIONS

This application is a Continuation of PCT International Application No. PCT/JP2024/015841 filed on Apr. 23, 2024, which claims priority under 35 U.S.C. § 119(a) to Japanese Patent Application No. 2023-080666 filed on May 16, 2023. The above applications are hereby expressly incorporated by reference, in their entirety, into the present application.

### BACKGROUND OF THE INVENTION

### 1. Field of the Invention

The present invention relates to a composition for treating a semiconductor device and a method for manufacturing a modified substrate.

### 2. Description of the Related Art

In advanced semiconductors, there is a demand for technology which can form a wiring line having a width of approximately 10 nm.

Therefore, a method of selectively modifying a substrate having a fine region on a surface layer has been studied. For the selective modification method, a material capable of simply and highly selectively modifying the surface region is required, and various materials have been studied.

For example, JP2022-161919A discloses, as a selective modification method and a composition capable of simply, highly selectively, and highly densely modifying a surface region of a substrate surface, containing a metal, “composition used in a selective modification method of a substrate surface having a first region containing a metal on a surface layer, in which the composition contains a polymer which has, at a terminal of a main chain or a side chain, a group including a first functional group forming a coordinate bond with the metal, and a solvent, and the first functional group is a cyano group, a sulfanyl group, an ethylenic carbon-carbon double bond-containing group, an oxazoline ring-containing group, a phosphoric acid group, an epoxy group, or a disulfide group”.

It is also disclosed that the polymer used in the above-described composition may further have a crosslinkable group such as a polymerizable carbon-carbon double bond-containing group.

### SUMMARY OF THE INVENTION

Here, the composition used for the selective surface modification described above is required to have the same performance as prior to storage even after being stored for a certain period of time.

As a result of studying characteristics of the composition containing the polymer having an ethylenically unsaturated group such as the polymerizable carbon-carbon double bond-containing group, disclosed in JP2022-161919A, the present inventors have confirmed that the above-described performance is not exhibited. More specifically, the composition containing the polymer having the polymerizable functional group is stored for a certain period of time, and the characteristics thereof are evaluated by bringing it into contact with a substrate having a surface containing a metal atom and a surface not containing a metal atom. In a case of the composition before the storage, the coating film is preferentially formed on the surface containing a metal atom; but in a case of the composition after the storage, the coating film is easily formed on the surface not containing a metal atom, and the surface containing a metal atom is not easily selectively modified.

Therefore, an object of the present invention is to provide a composition for treating a semiconductor device, which can preferentially form a coating film on a first surface in a case of being brought into contact with a substrate having a first surface containing a metal atom and a second surface not containing a metal atom, and can selectively form a coating film on the first surface even after storage.

Another object of the present invention is to provide a method for manufacturing a modified substrate using the above-described composition for treating a semiconductor device.

As a result of conducting an extensive investigation to achieve the objects, the present inventors have found that the objects can be achieved by the following configuration.

[1] A composition for treating a semiconductor device, comprising:
a polymer having a functional group which interacts with a surface containing a metal atom in a substrate and an ethylenically unsaturated group;
a polymerization inhibitor; and
a solvent.

[2] The composition for treating a semiconductor device according to [1],
in which the functional group is a group selected from the group consisting of a nitrogen-containing group, a phosphoric acid group or a salt thereof, a carboxy group or a salt thereof, a hydroxy group, an epoxy group, a hydrolyzable silyl group, a thiol group, and a disulfide group.

[3] The composition for treating a semiconductor device according to [1] or [2],
in which the functional group is a cyano group, or a phosphoric acid group or a salt thereof.

[4] The composition for treating a semiconductor device according to any one of [1] to [3],
in which the ethylenically unsaturated group is a group selected from the group consisting of a vinyl group, a vinyl ether group, a styryl group, an acryloyl group, and a methacryloyl group.

[5] The composition for treating a semiconductor device according to any one of [1] to [3],
in which the ethylenically unsaturated group is a group selected from the group consisting of an alkenyl group having 2 to 4 carbon atoms and an alkenylene group having 2 to 4 carbon atoms.

[6] The composition for treating a semiconductor device according to any one of [1] to [5],
in which the polymer includes a ring structure.

[7] The composition for treating a semiconductor device according to any one of [1] to [6],
in which the polymer includes an aromatic ring structure.

[8] The composition for treating a semiconductor device according to any one of [1] to [7],
in which the polymerization inhibitor contains a nitrogen atom.

[9] The composition for treating a semiconductor device according to any one of [1] to [8],
in which the polymerization inhibitor includes at least one compound selected from the group consisting of a phenol-based compound, a quinone-based compound, a free radical-based compound, an amine-based compound, a phosphine-based compound, and a thiol ether-based compound.

[10] The composition for treating a semiconductor device according to any one of [1] to [9],
in which the polymerization inhibitor is a phenol-based compound, a quinone-based compound, or a free radical-based compound.

[11] The composition for treating a semiconductor device according to any one of [1] to [10],
in which a content of the polymerization inhibitor is 0.08 to 200 parts by mass with respect to 100 parts by mass of the polymer.

[12] The composition for treating a semiconductor device according to any one of [1] to [11],
in which the solvent includes at least one solvent selected from the group consisting of an ester-based solvent, a ketone-based solvent, and an alcohol-based solvent.

[13] The composition for treating a semiconductor device according to any one of [1] to [12],
in which the solvent includes at least one solvent selected from the group consisting of propylene glycol monomethyl ether acetate, ethyl lactate, γ-butyrolactone, cyclohexanone, methyl isobutyl ketone, and propylene glycol monomethyl ether.

[14] A method for manufacturing a modified substrate, comprising:
a step of bringing a substrate having a first surface containing a metal atom and a second surface not containing a metal atom into contact with the composition for treating a semiconductor device according to any one of [1] to [13]; and
a step of subjecting the substrate brought into contact with the composition to a heating treatment to form a coating film on the first surface.

[15] The method for manufacturing a modified substrate according to [14],
in which the second surface contains an insulator.

[16] The method for manufacturing a modified substrate according to [14] or [15],
in which the second surface contains silicon.

[17] The method for manufacturing a modified substrate according to any one of [14] to [16],
in which the second surface contains silicon oxide, silicon nitride, or silicon oxycarbide.

According to the present invention, it is possible to provide a composition for treating a semiconductor device, which can preferentially form a coating film on a first surface in a case of being brought into contact with a substrate having a first surface containing a metal atom and a second surface not containing a metal atom, and can selectively form a coating film on the first surface even after storage.

In addition, it is also possible to provide a method for manufacturing a modified substrate using the above-described composition for treating a semiconductor device.

### BRIEF DESCRIPTION OF THE DRAWINGS

FIG. 1 is a cross-sectional view of a substrate for producing a stripe-shaped substrate.

FIG. 2 is a cross-sectional view of a stripe-shaped substrate used for evaluating selective surface modification.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

In the present specification, a numerical range represented by “to” means a range including numerical values before and after “to” as a lower limit value and an upper limit value.

In the present specification, a hydrogen atom may be a light hydrogen atom (normal hydrogen atom) or a heavy hydrogen atom (for example, a deuterium atom or the like).

A compound described in the present specification may include a structural isomer, an optical isomer, and an isotope unless otherwise specified. In addition, one kind of structural isomer, optical isomer, and isotope alone, or two or more kinds thereof may be included.

In citations for a group (atomic group) in the present specification, in a case where the group is cited without specifying whether it is substituted or unsubstituted, the group includes both a group having no substituent and a group having a substituent. For example, “alkyl group” includes not only an alkyl group having no substituent (unsubstituted alkyl group), but also an alkyl group having a substituent (substituted alkyl group).

Unless otherwise specified, “substituent” in the present specification is preferably a monovalent substituent.

Examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxyl group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; an alkylthio group; and a combination thereof.

A bonding direction of divalent groups cited in the present specification is not limited unless otherwise specified. For example, in a case where Y in a compound represented by Formula “X-Y-Z” is —COO—, Y may be —CO—O— or —O—CO—. In addition, the above-described compound may be “X—CO—O—Z” or “X—O—CO—Z”.

In the present specification, regarding a compound which may have a geometric isomer (cis-trans isomer), a formula representing the compound may be described only in the form of either a cis isomer or a trans isomer for convenience. Even in such a case, unless otherwise specified, the form of the compound is not limited to either the cis isomer or the trans isomer, and the compound may be the cis isomer or the trans isomer.

In the present specification, “(meth)acryl” is a generic term including acryl and methacryl, and means “at least one of acryl or methacryl”. Similarly, “(meth)acrylic acid” means “at least one of acrylic acid or methacrylic acid”.

In the present specification, “radiation” means, for example, a bright line spectrum of a mercury lamp, far ultraviolet rays typified by an excimer laser, extreme ultraviolet rays (EUV light), X-rays, electron beams (EB), or the like. “Light” in the present specification means actinic ray or radiation.

In the present specification, unless otherwise specified, a weight-average molecular weight (Mw), a number-average molecular weight (Mn), and a dispersity (also referred to as a molecular weight distribution) (Mw/Mn) of a polymer are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

### Composition for Treating Semiconductor Device

Hereinafter, the composition for treating a semiconductor device according to the embodiment of the present invention (hereinafter also simply referred to as “composition”) will be described in detail.

The composition is a composition for treating a semiconductor device containing a polymer having a functional group which interacts with a surface containing a metal atom in a substrate and an ethylenically unsaturated group, a polymerization inhibitor, and a solvent.

The mechanism by which the object of the present invention can be achieved by adopting the above-described configuration of the composition is not necessarily clear, but is presumed to be as follows by the present inventors.

The mechanism by which the effect is obtained is not limited by the following supposition. In other words, even in a case where an effect is obtained by a mechanism other than the following, it is included in the scope of the present invention.

The composition disclosed in JP2022-161919A contains a polymer having a repeating unit containing an ethylenic double bond in order to densely modify the substrate, but the ethylenic double bond undergoes unintended polymerization depending on storage conditions of the composition, which leads to an increase in molecular weight of the polymer.

Although the detailed mechanism is not clear, in a case where the composition in which the molecular weight of the polymer is increased as described above and the substrate are brought into contact with the composition, the polymerized polymer is likely to remain even on the second surface of the substrate not containing a metal, and thus it is difficult to preferentially form the coating film on the first surface containing a metal.

On the other hand, it is presumed that the composition according to the embodiment of the present invention contains the polymerization inhibitor to suppress the increase in molecular weight of the polymer described above, and thus the coating film can be formed preferentially on the first surface even after storage of the composition.

Hereinafter, each component which can be contained in the composition for treating a semiconductor device according to the embodiment of the present invention will be described in detail.

In addition, the effect that, in a case of being brought into contact with a substrate having a first surface containing a metal atom and a second surface not containing a metal atom, the coating film can be formed preferentially on the first surface and the coating film can be formed preferentially on the first surface even after storage is also referred to as “effect of the present invention is more excellent”.

### Polymer

The composition contains a polymer having a functional group which interacts with a surface containing a metal atom in a substrate (hereinafter, also simply referred to as “specific functional group”), and an ethylenically unsaturated group.

Hereinafter, the specific functional group and the ethylenically unsaturated group will be described.

### Functional Group Which Interacts With Surface Containing Metal Atom in Substrate

The polymer has a functional group which interacts with a surface containing a metal atom in a substrate. The specific functional group can interact with the surface containing a metal atom in the substrate. Therefore, in a substrate having a first surface containing a metal atom and a second surface not containing a metal atom, which will be described later, the specific functional group is likely to interact with the first surface more than with the second surface.

Examples of the interaction include a chemical bond, and more specific examples thereof include a covalent bond, an ionic bond, and a coordinate bond.

Examples of the surface containing a metal atom include the first surface containing a metal atom in the substrate described later. Examples of the metal atom contained in the surface containing a metal atom include a metal atom contained in the first surface described later

Examples of the specific functional group include a group selected from the group consisting of a nitrogen-containing group, a phosphoric acid group or a salt thereof, a carboxy group or a salt thereof, a hydroxy group, a hydroxyboron-containing group, an epoxy group, a hydrolyzable silyl group, a thiol group, and a disulfide group; and among these, a group selected from the group consisting of a nitrogen-containing group, a phosphoric acid group or a salt thereof, a carboxy group or a salt thereof, a hydroxy group, an epoxy group, a hydrolyzable silyl group, a thiol group, and a disulfide group is preferable, and a cyano group, or a phosphoric acid group or a salt thereof is more preferable.

The hydroxy group may be a phenolic hydroxy group.

Examples of the nitrogen-containing group include a cyano group (—C≡N), a primary amino group (—NH₂), a secondary amino group (—NR^{T}H), a tertiary amino group (—NR^{T}₂), and a quaternary ammonium group (—N⁺R^{T}₃); and among these, a cyano group, a primary amino group, a secondary amino group, or a tertiary amino group is preferable, and a primary amino group is more preferable.

R^{T} represents an alkyl group having 1 to 3 carbon atoms, and a plurality of R^{T}'s may be different from each other.

In addition, the nitrogen-containing group may have a ring structure containing a nitrogen atom as a ring member atom, and the ring structure may be a monocyclic ring or a polycyclic ring. Examples of the nitrogen-containing group having the above-described ring structure include a nitrogen-containing aliphatic heterocyclic group and a nitrogen-containing heteroaryl group.

Examples of the nitrogen-containing aliphatic heterocyclic group include groups having a ring structure such as an oxazoline ring, a pyrrolidine ring, a piperidine ring, and a piperazine ring.

Examples of the nitrogen-containing heteroaryl group include a pyridyl group, a triazine group, a pyrrole group, a pyrazole group, an imidazole group, a triazole group, a benzimidazole group, and a benztriazole group.

The salt of the phosphoric acid group refers to a group represented by —PO₄²⁻Ctⁿ⁺_{2/n}. Ctⁿ⁺ represents an n-valent cation, where n represents 1 or 2. Examples of the monovalent cation include Li⁺, Na⁺, K⁺, and NH₄⁺. In a case where Ctⁿ⁺ represents a monovalent cation, the number thereof is 2. Examples of the divalent cation include Mg²⁺ and Ca²⁺. In a case where Ctⁿ⁺ represents a divalent cation, the number thereof is 1.

A compound having a phosphoric acid group is also referred to as “phosphate compound”, and a functional group name is also referred to as “phosphate”.

The salt of the carboxy group refers to a group represented by —COO⁻Ct⁺. Ct⁺ represents a monovalent cation, and examples thereof include the same cations as the monovalent cations described in the salt of the phosphoric acid group above.

Examples of the hydrolyzable silyl group include an alkoxysilyl group and a chlorosilyl group (group having an —Si—Cl structure).

In the alkoxysilyl group, the number of alkoxy groups bonded to the silicon atom (Si atom) is not particularly limited, but is preferably 2 or more, and more preferably 3.

Among these, a trimethoxysilyl group or a triethoxysilyl group is preferable as the alkoxysilyl group.

In the chlorosilyl group, the number of chlorine atoms bonded to the Si atom is preferably 1 to 3, and more preferably 1. In a case where the number of chlorine atoms described above is 1 or 2, the chlorosilyl group is preferably a dialkyl monochlorosilyl group or a monoalkyl dichlorosilyl group.

The above-described alkyl group may be linear, cyclic, or branched, but is preferably linear. Among these, a methyl group is preferable as the alkyl group.

In the polymer, it is preferable that the specific functional group is present at a terminal of the main chain or a terminal of the side chain. Among these, from the viewpoint that the effect of the present invention is more excellent, it is preferable that the specific functional group is present at one terminal of the main chain.

Examples of a method of introducing the specific functional group at the terminal of the main chain include a method of using a compound containing the specific functional group as a radical polymerization initiator for synthesizing the polymer, and a method of using a compound containing the specific functional group as an anionic polymerization terminating agent for synthesizing the polymer.

Examples of the initiator containing the specific functional group include a cyano group-containing initiator such as azobisisobutyronitrile (AIBN). Examples of the terminating agent containing the specific functional group include a boroxine compound, a cyano group-containing halide, an epoxy group-containing halide, and a carbon-carbon triple bond-containing halide.

Examples of a method of introducing the specific functional group at the terminal of the side chain include a method of polymerizing a monomer having the specific functional group at the terminal to form a repeating unit having the specific functional group at the terminal of the side chain (hereinafter, also referred to as “repeating unit X”).

Examples of the monomer having the specific functional group include vinylphosphoric acid, hydroxystyrene or a protected substance thereof, and epoxy group-containing vinyl ether.

From the viewpoint that the effect of the present invention is more excellent, the repeating unit X is preferably present in a block form in the polymer, and more preferably present in a block form at one terminal of the main chain.

From the viewpoint that the effect of the present invention is more excellent, a content of the repeating unit X is preferably 0.1% by mole or more, more preferably 0.5% by mole or more, still more preferably 1% by mole or more, and particularly preferably 3% by mole or more with respect to all repeating units of the polymer.

The upper limit thereof is preferably 30% by mole or less, more preferably 10% by mole or less, and still more preferably 8% by mole or less.

### Ethylenically Unsaturated Group

The “ethylenically unsaturated group” refers to a group having a double bond between carbon atoms (C═C), and is usually a monovalent group or a divalent group. The ethylenically unsaturated group does not contain an aromatic conjugated double bond between carbon atoms constituting an aromatic ring. The ethylenically unsaturated group is not particularly limited as long as it is a group containing a double bond between carbon atoms; and examples thereof include a group which can form a crosslinking structure by a reaction under a heating condition, an active energy ray irradiation condition, or an acidic condition.

More specific examples of the ethylenically unsaturated group include a vinyl group, a vinyl ether group (vinyloxy group), an allyl group, an acryloyl group, a methacryloyl group, and a styryl group.

Among these, the ethylenically unsaturated group is preferably a vinyl group, a vinyl ether group, a styryl group, an acryloyl group, or a methacryloyl group.

In addition, it is also preferable that the ethylenically unsaturated group is a group selected from the group consisting of an alkenyl group having 2 to 4 carbon atoms and an alkenylene group having 2 to 4 carbon atoms.

In the present specification, the alkenyl group is a group formed by removing one hydrogen atom from an aliphatic hydrocarbon having the double bond in the molecule; and the alkenylene group is a group formed by removing two hydrogen atoms from an aliphatic hydrocarbon having the double bond in the molecule.

Examples of the alkenyl group having 2 to 4 carbon atoms include a vinyl group, an allyl group, an isopropenyl group, and an isobutenyl group. Examples of the alkenylene group having 2 to 4 carbon atoms include a vinylidene group and a methylvinylidene group.

The polymer may have the ethylenically unsaturated group in the main chain or in the side chain; but from the viewpoint of further promoting crosslinking of the polymer during heating and being able to perform modification with higher density, it is preferable that the polymer has the ethylenically unsaturated group in the main chain and the side chain.

Examples of a method of introducing the ethylenically unsaturated group into the polymer include a method of synthesizing the polymer using a monomer which provides a repeating unit containing an ethylenic double bond (hereinafter, also referred to as “repeating unit A”).

### Repeating Unit A

The repeating unit A may have one ethylenic double bond or may have two or more ethylenic double bonds.

Examples of a structure containing the ethylenic double bond include an isolated double bond structure such as an ethylene structure and a propylene structure, a conjugated double bond structure such as a butadiene structure and a hexatriene structure, and a carbonyl group-conjugated double bond structure such as an acrylic structure and a methacrylic structure.

Examples of the repeating unit A include repeating units represented by Formulae (1-1) to (1-3) (hereinafter, also referred to as “repeating units (A-1) to (A-3)”).

The repeating unit (A-1) contains the ethylenic double bond in the main chain. The repeating unit (A-2) contains the ethylenic double bond in the main chain and the side chain. The repeating unit (A-3) contains the ethylenic double bond in the side chain.

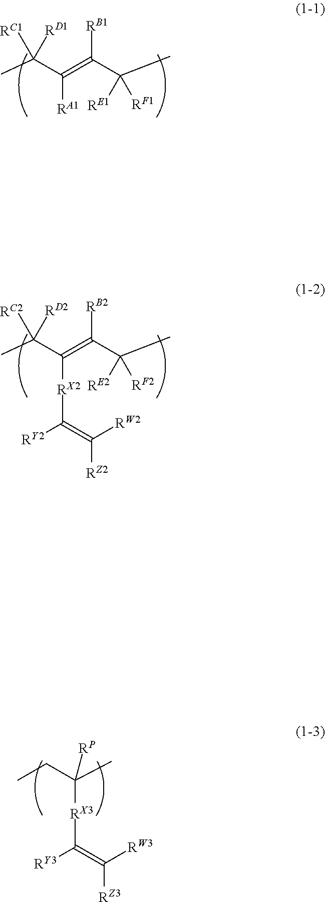

In Formula (1-1), R^{A1} to R^{F1} each independently represent a hydrogen atom, a halogen atom, or a monovalent organic group having 1 to 20 carbon atoms.

In Formula (1-2), R^{B2} to R^{F2} each independently represent a hydrogen atom, a halogen atom, or a monovalent organic group having 1 to 20 carbon atoms. R^{X2} represents a single bond or a divalent organic group having 1 to 20 carbon atoms. R^{Y2}, R^{Z2}, and R^{W2} each independently represent a hydrogen atom, a halogen atom, or a monovalent organic group having 1 to 20 carbon atoms.

In Formula (1-3), RP represents a hydrogen atom or a methyl group. R^{X3} represents a single bond or a divalent organic group having 1 to 20 carbon atoms. R^{Y3}, R^{Z3}, and R^{W3} each independently represent a hydrogen atom, a halogen atom, or a monovalent organic group having 1 to 20 carbon atoms.

In Formula (1-1), R^{A1} and R^{B1} are preferably a monovalent organic group, and RCI to R^{F1} are preferably a hydrogen atom.

The “organic group” refers to a group containing at least one carbon atom.

More specific examples of the monovalent organic group having 1 to 20 carbon atoms represented by R^{A1} to R^{F1} include an aliphatic hydrocarbon group and an aromatic ring group.

The above-described aliphatic hydrocarbon group may be linear, branched, or cyclic, and preferably has 1 to 15 carbon atoms, more preferably 1 to 10 carbon atoms, and still more preferably 1 to 3 carbon atoms.

The cyclic aliphatic hydrocarbon group may be monocyclic or polycyclic. Here, the cyclic aliphatic hydrocarbon group does not need to be composed of only an alicyclic structure, and a chain structure may be included in a part thereof.

Examples of the linear or branched aliphatic hydrocarbon group having 1 to 20 carbon atoms include an alkyl group such as a methyl group, an ethyl group, a n-propyl group, and an i-propyl group; an alkenyl group such as an ethenyl group, a propenyl group, and a butenyl group; and an alkynyl group such as an ethynyl group, a propynyl group, and a butynyl group.

Examples of the cyclic aliphatic hydrocarbon group having 3 to 20 carbon atoms include a monocyclic alicyclic saturated hydrocarbon group such as a cyclopentyl group and a cyclohexyl group; a monocyclic alicyclic unsaturated hydrocarbon group such as a cyclopentenyl group and a cyclohexenyl group; a polycyclic alicyclic saturated hydrocarbon group such as a norbornyl group, an adamantyl group, and a tricyclodecyl group; and a polycyclic alicyclic unsaturated hydrocarbon group such as a norbornenyl group and a tricyclodecenyl group.

The above-described aromatic ring group may be an aryl group or a heteroaryl group.

The number of ring members in an aromatic ring constituting the aromatic ring group is preferably 5 to 15, more preferably 5 to 10, and still more preferably 5 or 6.

In addition, the aromatic ring constituting the aromatic ring group may be a monocyclic ring or a polycyclic ring (fused ring). The above-described fused ring may have a structure in which a plurality of aromatic rings are fused to each other or a structure in which one or more aromatic rings and one or more non-aromatic rings are fused to each other.

Examples of the monovalent aromatic hydrocarbon group having 6 to 20 carbon atoms include an aryl group such as a phenyl group, a tolyl group, a xylyl group, a naphthyl group, and an anthryl group; and an aralkyl group such as a benzyl group, a phenethyl group, a naphthylmethyl group, and an anthrylmethyl group.

The aromatic ring group may have a substituent.

The “organic group” may have at least one of a heteroatom or a halogen atom. Examples of the organic group having at least one of a heteroatom or a halogen atom include a group having a divalent heteroatom-containing group at a carbon-carbon or a terminal on a bonding site of the above-described hydrocarbon group, and a group in which a part or all of hydrogen atoms contained in the above-described hydrocarbon group or the group having the divalent heteroatom-containing group is substituted with a monovalent heteroatom-containing group or a halogen atom.

Examples of the heteroatom include an oxygen atom, a nitrogen atom, a sulfur atom, a phosphorus atom, and a silicon atom.

Examples of the halogen atom include a fluorine atom, a chlorine atom, a bromine atom, and an iodine atom.

Examples of the monovalent heteroatom-containing group include a hydroxy group, a carboxy group, a cyano group, an amino group, and a thiol group.

Examples of the divalent heteroatom-containing group include —O—, —CO—, —S—, —CS—, —NR^{H}—, and a group formed by a combination of two or more of these groups. R^{H} is a hydrogen atom or a monovalent hydrocarbon group.

In Formula (1-2), examples of the monovalent organic group having 1 to 20 carbon atoms, represented by R^{B2} to R^{F2}, include the above-described monovalent organic group exemplified as R^{A1} to R^{F1} in Formula (1-1).

Examples of the divalent organic group having 1 to 20 carbon atoms, represented by R^{X2}, include a group obtained by removing one hydrogen atom from the above-described monovalent organic group exemplified as R^{A1} to R^{F1} in Formula (1-1).

R^{X2} is preferably a divalent hydrocarbon group, more preferably an alkanediyl group, and still more preferably a methanediyl group or an ethanediyl group.

Examples of the monovalent organic group having 1 to 20 carbon atoms, represented by R¹², R^{Z2}, and R^{W2}, include the above-described monovalent organic group exemplified as R^{A1} to R^{F1} in Formula (1-1).

R^{Y2} is preferably a hydrogen atom. R^{Z2} and R^{W2} are preferably a monovalent hydrocarbon group, more preferably an alkyl group, and still more preferably a methyl group.

In Formula (1-3), R^{P} is preferably a hydrogen atom.

Examples of the divalent organic group having 1 to 20 carbon atoms, represented by R^{X3}, include a group obtained by removing one hydrogen atom from the above-described monovalent organic group exemplified as R^{A1} to R^{F1} in Formula (1-1).

Examples of the monovalent organic group having 1 to 20 carbon atoms, represented by R^{Y3}, R^{Z3}, and R^{W3}, include the above-described monovalent organic group exemplified as R^{A1} to R^{F1} in Formula (1-1).

R^{Y3} is preferably a hydrogen atom. R²³ and R^{W3} are preferably a monovalent hydrocarbon group, more preferably an alkyl group, and still more preferably a methyl group.

Examples of the monomer providing the repeating unit (A-1) include a compound having a conjugated double bond, such as butadiene and isoprene; examples of the monomer providing the repeating unit (A-2) include a compound having a conjugated double bond and an isolated double bond, such as myrcene; and examples of the monomer providing the repeating unit (A-3) include a compound having a plurality of isolated double bonds, such as 4-allylstyrene and 1,5-hexadiene.

A content of the repeating unit A is preferably 0.1% by mole or more, more preferably 1% by mole or more, still more preferably 5% by mole or more, and particularly preferably 8% by mole or more with respect to all repeating units of the polymer.

The upper limit thereof is preferably 90% by mole or less, more preferably 50% by mole or less, still more preferably 30% by mole or less, and particularly preferably 20% by mole or less.

The polymer preferably includes a ring structure in the structure, and more preferably includes an aromatic ring structure. For example, the polymer may have a repeating unit having an aromatic ring (hereinafter, also referred to as “repeating unit B”) as a repeating unit different from the above-described repeating unit A.

### Repeating Unit B

The repeating unit B is a repeating unit including an aromatic ring.

Examples of the aromatic ring include a benzene ring, a fused benzene ring, and a heteroaromatic ring. The number of ring members in the aromatic ring is preferably 5 to 20 and more preferably 5 to 10.

More specifically, examples of the benzene ring and the fused benzene ring include a naphthalene ring, an anthracene ring, a phenanthrene ring, a tetracene ring, and a pyrene ring; and examples of the heteroaromatic ring include a nitrogen atom-containing aromatic ring such as a pyrrole ring, a pyridine ring, a pyrazine ring, and a quinoline ring, an oxygen atom-containing aromatic ring such as a furan ring, a pyran ring, a chromene ring, and a xanthene ring, and a sulfur atom-containing aromatic ring such as a thiophene ring and a benzothiophene ring.

Examples of the repeating unit B include a repeating unit represented by Formula (2).

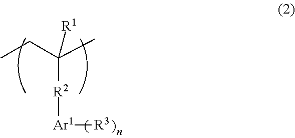

In Formula (2), Ar¹ represents a group obtained by removing (n+1) hydrogen atoms from an aromatic ring in an arylene having 6 to 20 ring members or a heteroarylene having 5 to 20 ring members. n represents an integer of 0 to 11. n is preferably 0 to 3.

R¹ represents a hydrogen atom or a methyl group. R¹ is preferably a hydrogen atom.

R² represents a single bond, —O—, —COO—, or —CONH—. R² is preferably a single bond or —COO—, and more preferably a single bond.

R³ represents an amino group, a carboxy group, a hydroxy group, a nitro group, a halogen atom, or a monovalent organic group having 1 to 20 carbon atoms. In a case where n is 2 or more, a plurality of R³'s may be the same or different from each other.

Examples of the arylene having 6 to 20 ring members, which provides Ar¹, include benzene, naphthalene, anthracene, phenanthrene, tetracene, and pyrene.

Examples of the heteroarylene having 5 to 20 ring members, which provides Ar¹, include a nitrogen atom-containing aromatic heterocyclic compound such as pyrrole, pyridine, pyrazine, and quinoline; an oxygen atom-containing aromatic heterocyclic compound such as furan, pyran, chromene, and xanthene; and a sulfur atom-containing aromatic heterocyclic compound such as thiophene and benzothiophene.

Examples of the monovalent organic group having 1 to 20 carbon atoms, represented by R³, include the above-described monovalent organic group exemplified as R^{A1} to R^{F1} in Formula (1-1).

R³ is preferably a monovalent organic group, more preferably a hydrocarbon group which may have a substituent, and still more preferably an aliphatic hydrocarbon group which may have a substituent. The aliphatic hydrocarbon group may be linear, branched, or cyclic.

Examples of the substituent which may be included in the above-described hydrocarbon group include an alkoxy group such as a hydroxy group, a methoxy group, and an ethoxy group, and a halogen atom such as a fluorine atom, a chlorine atom, a bromine atom, and an iodine atom.

Examples of the monomer which provides the repeating unit B include styrene derivatives such as styrene, α-methylstyrene, o-methylstyrene, m-methylstyrene, p-methylstyrene, p-tert-butylstyrene, 2,4,6-trimethylstyrene, p-methoxystyrene, p-tert-butoxystyrene, o-vinylstyrene, m-vinylstyrene, p-vinylstyrene, o-hydroxystyrene, m-hydroxystyrene, p-hydroxystyrene, m-chloromethylstyrene, p-chloromethylstyrene, p-chlorostyrene, p-bromostyrene, p-iodostyrene, p-nitrostyrene, and p-cyanostyrene, and aromatic ring-containing (meth)acrylates such as phenyl (meth)acrylate and naphthyl (meth)acrylate.

The repeating unit B is preferably a repeating unit derived from styrene which may have a substituent, and more preferably a repeating unit derived from styrene.

The polymer may have the repeating unit A and the repeating unit B in a block form or in a random form; but from the viewpoint of further increasing insolubility of the polymer during heating, the random form is preferable.

A content of the repeating unit B is preferably 10% by mole or more, more preferably 40% by mole or more, still more preferably 60% by mole or more, and particularly preferably 80% by mole or more with respect to all repeating units of the polymer.

The upper limit thereof is preferably 99% by mole or less, more preferably 95% by mole or less, and still more preferably 92% by mole or less.

### Other repeating units

The polymer may have a repeating unit other than the repeating unit A and the repeating unit B described above.

Examples of other repeating units include a repeating unit derived from a (meth)acrylic acid ester and a repeating unit derived from an ethylene which may have a substituent.

Examples of the (meth)acrylic acid ester include a (meth)acrylic acid alkyl ester such as methyl (meth)acrylate, ethyl (meth)acrylate, tert-butyl (meth)acrylate, and 2-ethylhexyl (meth)acrylate; a (meth)acrylic acid cycloalkyl ester such as cyclopentyl (meth)acrylate, cyclohexyl (meth)acrylate, 1-methylcyclopentyl (meth)acrylate, 2-ethyladamantyl (meth)acrylate, and 2-(adamantan-1-yl)propyl (meth)acrylate; and a (meth)acrylic acid-substituted alkyl ester such as 2-hydroxyethyl (meth)acrylate, 3-hydroxyadamantyl (meth)acrylate, 3-glycidylpropyl (meth)acrylate, and 3-trimethylsilylpropyl (meth)acrylate.

Examples of the ethylene which may have a substituent include an alkene such as propene, butene, and pentene; a vinylcycloalkane such as vinylcyclopentane and vinylcyclohexane; a cycloalkene such as cyclopentene and cyclohexene; and vinyl phosphate, 4-hydroxy-1-butene, vinyl glycidyl ether, and vinyl trimethylsilyl ether.

In a case where the polymer has other repeating units, a content of the other repeating units is preferably 30% by mole or less, more preferably 20% by mole or less, still more preferably 10% by mole or less, and particularly preferably 6% by mole or less with respect to all repeating units of the polymer.

The lower limit thereof is preferably, for example, 0.1% by mole or more.

In a case where the polymer has other repeating units, the other repeating units may be present in the polymer in a block form, or may be present in a random form with respect to the repeating unit A or the repeating unit B.

A weight-average molecular weight (Mw) of the polymer is preferably 1,000 or more, more preferably 2,000 or more, still more preferably 3,000 or more, and particularly preferably 4,000 or more. The upper limit thereof is preferably 50,000 or less, more preferably 30,000 or less, still more preferably 10,000 or less, and particularly preferably 7,000 or less.

A dispersity (Mw/Mn; molecular weight distribution) of the polymer is preferably 5 or less, more preferably 2 or less, still more preferably 1.5 or less, and particularly preferably 1.3 or less. The lower limit thereof is preferably 1.1 or more.

A content of the polymer is preferably 15% by mass or more, more preferably 80% by mass or more, still more preferably 90% by mass or more, and particularly preferably 95% by mass or more with respect to the total solid content of the composition. The upper limit thereof is preferably 99.9% by mass or less, more preferably 99% by mass or less, and particularly preferably 98% by mass or less. The “total solid content” refers to the sum of components contained in the composition, other than the solvent described later.

### Polymerization Inhibitor

The composition contains a polymerization inhibitor.

The polymerization inhibitor is not particularly limited, but is preferably a radical polymerization inhibitor.

In addition, it is also preferable that the polymerization inhibitor contains a nitrogen atom. The nitrogen atom is easily adsorbed on a metal such as copper, but is not adsorbed on a non-metal such as silicon oxide. Therefore, the polymerization inhibitor containing the nitrogen atom is easily adsorbed on a surface containing a metal atom such as copper.

Furthermore, since the specific functional group in the polymer, such as the phosphoric acid group, is easily adsorbed on a nitrogen atom, the polymer is more likely to be deposited on the surface containing a metal atom such as copper, starting from the polymerization inhibitor adsorbed on the surface containing a metal atom, so that selectivity of the polymer to the surface containing a metal atom with respect to the surface not containing a metal atom is improved.

The polymerization inhibitor preferably includes at least one compound selected from the group consisting of a phenol-based compound, a quinone-based compound, a free radical-based compound, an amine-based compound, a phosphine-based compound, and a thiol ether-based compound, and from the viewpoint that the effect of the present invention is more excellent, it is more preferable that the polymerization inhibitor is a phenol-based compound, a quinone-based compound, or a free radical-based compound.

Examples of the phenol-based compound include 4-methoxyphenol, hydroquinone, 2-tert-butylhydroquinone, 4-tert-butylcatechol, pentaerythritol tetrakis[3-(3,5-di-tert-butyl-4-hydroxyphenyl)propionate], 2,5-di-tert-butyl-4-methylphenol, 2,6-di-tert-butyl-4-methylphenol, 4,4′-thiobis(3-methyl-6-tert-butylphenol), 2,2′-methylenebis(4-methyl-6-tert-butylphenol), 4-methoxynaphthol, 2,4-bis(octylthiomethyl)-6-methylphenol, p-nitrosophenol, and α-nitroso-β-naphthol.

Examples of the quinone-based compound include 1,4-benzoquinone, 1,2-benzoquinone, and 1,4-naphthoquinone.

Examples of the free radical-based compound include poly(4-methacryloyloxy-2,2,6,6-tetramethylpiperidin-N-oxyl), 4-hydroxy-2,2,6,6-tetramethylpiperidine 1-oxyl, 2,2,6,6-tetramethylpiperidine 1-oxyl, 2,2-diphenyl-1-picrylhydrazyl, and triphenylverdazyl.

Among these, as the free radical-based compound, a nitroxyl radical-based compound is preferable, and a nitroxyl radical-based compound having a piperidine skeleton is more preferable. Examples of the nitroxyl radical-based compound having a piperidine skeleton include poly(4-methacryloyloxy-2,2,6,6-tetramethylpiperidin-N-oxyl), 4-hydroxy-2,2,6,6-tetramethylpiperidine 1-oxyl, and 2,2,6,6-tetramethylpiperidine 1-oxyl.

Examples of the amine-based compound include p-phenylenediamine, 4-aminodiphenylamine, N,N-diethylhydroxylamine, N,N′-diphenyl-p-phenylenediamine, N-isopropyl-N′-phenyl-p-phenylenediamine, N-(1,3-dimethylbutyl)-N′-phenyl-p-phenylenediamine, N,N′-di-2-naphthyl-p-phenylenediamine, diphenylamine, N-phenyl-β-naphthylamine, 4,4′-dicumyl-diphenylamine, 4,4′-dioctyl-diphenylamine, phenothiazine, 2-methoxyphenothiazine, phenoxazine, N-nitrosodiphenylamine, N-nitrosophenylnaphthylamine, N-nitrosodinaphthylamine, p-nitrosodiphenylamine, N-nitroso-N-phenylhydroxylamine, N-nitroso-N-phenylhydroxylamine aluminum, and cupferron. Each of the compounds exemplified as the amine-based compound may form a metal salt or a metal complex.

Among these, a salt of the N-nitroso compound is preferable as the amine-based compound. Examples of the salt of the N-nitroso compound include N-nitroso-N-phenylhydroxylamine aluminum.

Examples of the phosphine-based compound include tris(2,4-di-tert-butylphenyl) phosphite.

In addition, examples of the polymerization inhibitor include a nitrobenzene-based compound such as nitrobenzene and 4-nitrotoluene, and a thiol ether-based compound such as dioctadecyl 3,3′-thiodipropionate, dilauryl thiodipropionate, dimyristyl thiodipropionate, and distearyl thiodipropionate.

A molecular weight of the polymerization inhibitor is preferably 1,000 or less, more preferably 800 or less, and still more preferably 500 or less. The lower limit of the above-described molecular weight is not particularly limited, but is preferably 80 or more.

A content of the polymerization inhibitor is preferably 0.0001% by mass or more, more preferably 0.001% by mass or more, still more preferably 0.005% by mass or more, and particularly preferably 0.010% by mass or more with respect to the total solid content of the composition. The upper limit thereof is preferably 70% by mass or less, more preferably 10% by mass or less, and particularly preferably 2% by mass or less.

In addition, from the viewpoint that the effect of the present invention is more excellent, the content of the polymerization inhibitor is preferably 0.001 parts by mass or more, more preferably 0.08 parts by mass or more, still more preferably 0.1 parts by mass or more, and particularly preferably 1.0 parts by mass or more with respect to 100 parts by mass of the above-described polymer.

The upper limit value thereof is preferably 200 parts by mass or less, more preferably 80 parts by mass or less, and still more preferably 10 parts by mass or less with respect to 100 parts by mass of the polymer.

The composition may contain one kind of the polymerization inhibitor alone, or may contain two or more kinds thereof. In a case of containing two or more kinds of the polymerization inhibitors, it is preferable that the total amount thereof is within the above-described range.

### Solvent

The composition contains a solvent. The solvent is not particularly limited as long as it is a solvent capable of dissolving or dispersing at least the polymer, the polymerization inhibitor, and an optional component to be added as necessary.

Examples of the solvent include water and an organic solvent.

Examples of the organic solvent include an ester-based solvent, a ketone-based solvent, an alcohol-based solvent, an ether-based solvent, a hydrocarbon-based solvent, an amide-based solvent, and a sulfur-containing solvent.

Examples of the ester-based solvent include n-butyl acetate, ethyl lactate, propylene glycol acetate, propylene glycol monomethyl ether acetate, γ-butyrolactone, and δ-valerolactone.

Examples of the ketone-based solvent include acetone, methyl ethyl ketone, methyl isobutyl ketone, and cyclohexanone.

Examples of the alcohol-based solvent include an aliphatic alcohol-based solvent having 1 to 18 carbon atoms, such as methanol, ethanol, 1-propanol, 2-propanol (also referred to as isopropyl alcohol (IPA)), 2-butanol, isobutyl alcohol, tert-butyl alcohol, isopentyl alcohol, and 4-methyl-2-pentanol (also referred to as methylisobutyl carbinol (MIBC)); an alicyclic alcohol-based solvent having 3 to 18 carbon atoms, such as cyclohexanol; an aromatic alcohol-based solvent such as benzyl alcohol; and a ketone alcohol-based solvent such as diacetone alcohol.

The number of carbon atoms in the alcohol-based solvent is preferably 1 to 8, more preferably 2 to 7, and still more preferably 3 to 6.

The alcohol-based solvent may be a polyol-based solvent or a glycol ether-based solvent.

Examples of the polyol-based solvent include a glycol-based solvent having 2 to 18 carbon atoms.

Examples of the glycol-based solvent include ethylene glycol, propylene glycol (1,2-propanediol), 1,3-propanediol, diethylene glycol, and dipropylene glycol.

Examples of the glycol ether-based solvent include a glycol monoether-based solvent having 3 to 19 carbon atoms.

Examples of the glycol monoether-based solvent include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol monomethyl ether, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

The number of carbon atoms in the glycol ether-based solvent is preferably 1 to 8, more preferably 2 to 7, and still more preferably 3 to 6.

Examples of the ether-based solvent include diethyl ether, diisopropyl ether, dibutyl ether, tert-butyl methyl ether, cyclohexyl methyl ether, and tetrahydrofuran.

Examples of the hydrocarbon-based solvent include an aliphatic hydrocarbon-based solvent such as n-pentane and n-hexane; an alicyclic hydrocarbon-based solvent such as cyclohexane and methylcyclohexane; and an aromatic hydrocarbon-based solvent such as toluene and xylene.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the sulfur-containing solvent include dimethyl sulfone, dimethyl sulfoxide, and sulfolane.

Among these, the solvent preferably includes at least one solvent selected from the group consisting of the ester-based solvent, the ketone-based solvent, and the alcohol-based solvent; and more preferably includes at least one solvent selected from the group consisting of propylene glycol monomethyl ether acetate, ethyl lactate, γ-butyrolactone, cyclohexanone, methyl isobutyl ketone, and propylene glycol monomethyl ether.

A content of the solvent is preferably 90% to 99.999% by mass, more preferably 95% to 99.9% by mass, and still more preferably 97% to 99.9% by mass with respect to the total mass of the composition.

A concentration of solid contents of the composition is preferably 0.1% by mass or more, more preferably 0.5% by mass or more, and still more preferably 1% by mass or more. The upper limit thereof is preferably 30% by mass or less, more preferably 10% by mass or less, and particularly preferably 3% by mass or less.

Two or more kinds of the solvents may be used in combination.

In a case where two or more kinds of the solvents are used in combination, the total content thereof is preferably within the range.

### Thermal Acid Generator

The composition may contain a thermal acid generator.

The thermal acid generator is a compound which generates an acid by heating. The thermal acid generator may be ionic or non-ionic.

In a case where the polymer contains the aromatic ring and the ethylenic double bond, the aromatic ring and the ethylenic double bond in the polymer may be crosslinked by a Friedel-Crafts reaction due to the action of the acid generated from the thermal acid generator.

Examples of the ionic thermal acid generator include a salt of a cation such as triphenylsulfonium, 1-dimethylthionaphthalene, 1-dimethylthio-4-hydroxynaphthalene, 4-hydroxyphenyldimethylsulfonium, 1-dimethylthio-4,7-dihydroxynaphthalene, benzyl-4-hydroxyphenylmethylsulfonium, 2-methylbenzyl-4-hydroxyphenylmethylsulfonium, 2-methylbenzyl-4-acetylphenylmethylsulfonium, 2-methylbenzyl-4-benzoyloxyphenylmethylsulfonium, 1-(4-n-butoxynaphthalene-1-yl)tetrahydrothiophenium, 1-(4,7-dibutoxynaphthalen-1-yl)tetrahydrothiophenium, diphenyliodonium, and di(tert-butylphenyl)iodonium, with an anion including methanesulfonate, a fluorinated alkyl sulfonate such as trifluoromethanesulfonate and nonafluorobutane-1-sulfonate, a sulfonate ion such as camphorsulfonate and a p-toluenesulfonate ion, a phosphoric acid ion such as a hexafluorophosphate ion, a boric acid ion such as a tetrafluoroborate ion, and an antimony acid ion such as a hexafluoroantimonate ion.

Examples of the non-ionic thermal acid generator include a halogen-containing compound, a diazomethane compound, a sulfone compound, a sulfonic acid ester compound, a carboxylic acid ester compound, a phosphoric acid ester compound, an N-sulfonyloxyimide compound, and a sulfone benzotriazole compound.

More specific examples of the N-sulfonyloxyimide compound include N-(trifluoromethylsulfonyloxy)succinimide and N-(2-trifluoromethylphenylsulfonyloxy)phthalimide.

An acid generation temperature of the thermal acid generator is preferably 80° C. or higher, more preferably 100° C. or higher, still more preferably 120° C. or higher, and particularly preferably 150° C. or higher. The upper limit thereof is preferably 250° C. or lower, more preferably 230° C. or lower, still more preferably 210° C. or lower, and particularly preferably 190° C. or lower.

The “acid generation temperature” of the thermal acid generator can be measured as a peak temperature of a maximum endothermic peak or a maximum exothermic peak in a DSC curve obtained by increasing a temperature from 30° C. to 300° C. under a condition of a temperature rising rate of 10° C./min.

A content of the thermal acid generator is preferably 0.1 parts by mass or more, more preferably 0.5 parts by mass or more, still more preferably 1 part by mass or more, and particularly preferably 2 parts by mass or more with respect to 100 parts by mass of the polymer. The upper limit thereof is preferably 400 parts by mass or less, more preferably 50 parts by mass or less, still more preferably 30 parts by mass or less, particularly preferably 10 parts by mass or less, and most preferably 6 parts by mass or less.

### Optional Components

The composition may contain an optional component in addition to the above-described respective components. Examples of the optional component include a surfactant.

### Method for Producing Composition

A method for producing the composition is not particularly limited, and the composition can be produced, for example, by mixing the above-described respective components.

An order or timing of mixing the respective components in the composition is not particularly limited. Examples of the method for producing the composition include a method in which the polymer and the polymerization inhibitor are added to a stirrer such as a mixing mixer, containing a purified solvent, and then sufficiently stirred to produce the composition.

In a case where the composition contains a component other than the polymer and the polymerization inhibitor, the other components may be added at the same time as the polymer and the polymerization inhibitor or at a different timing.

In the production step of producing the composition, steps described below may be performed.

### Metal Removal Step

In the above-described production method, a metal removal step of removing a metal component from the above-described components and/or the composition (hereinafter, also called “substance to be purified”) may be performed.

### Filtration Step

It is preferable that the above-described production method includes a filtration step of filtering the liquid in order to remove foreign substances, coarse particles, and the like from the liquid.

The filtration method is not particularly limited, and a well-known filtration method can be used. Among these, filtering using a filter is preferable. Examples of the filter include a high-density polyethylene filter having a fine hole of approximately 0.45 μm.

### Static Charge Removal Step

The method for producing the composition may further include a static charge removal step of statically neutralizing the composition.

### Method for Manufacturing Modified Substrate

The method for manufacturing a modified substrate according to the embodiment of the present invention (hereinafter, also simply referred to as “present manufacturing method”) includes a step of bringing a substrate having a first surface containing a metal atom and a second surface not containing a metal atom into contact with the above-described composition for treating a semiconductor device (hereinafter, also referred to as “composition layer forming step”); and a step of subjecting the substrate brought into contact with the composition to a heating treatment to form a coating film on the first surface (hereinafter, also referred to as “heating step”).

It is preferable that the present manufacturing method further includes, after the heating step, a step of removing a portion other than the coating film formed on the first surface with a rinsing liquid (hereinafter, also referred to as “removal step”).

In addition, the present manufacturing method may further include, for example, a step of bringing an alcohol, a dilute acid, ozone, or plasma into contact with the surface of the substrate after the removal step (hereinafter, also referred to as “contact step”); a step of depositing a pattern on the surface of the substrate after the removal step by a CVD method or an ALD method (hereinafter, also referred to as “deposition step”); a step of etching and removing the polymer on the surface of the substrate after the removal step (hereinafter, also referred to as “etching step”); or the like.

Hereinafter, the respective steps will be described.

### Composition Layer Forming Step

In the present step, the substrate and the above-described composition for treating a semiconductor device are brought into contact with each other to form a composition layer on a surface of the substrate.

Examples of the method of forming the composition layer on the substrate include various coating methods such as a slit coating method, an ink jet method, a spin coating method, a cast coating method, a roll coating method, and a screen printing method.

The substrate is a substrate having the first surface containing a metal atom and the second surface not containing a metal atom.

Examples of the metal atom include metal atoms such as copper, iron, zinc, cobalt, aluminum, tin, tungsten, zirconium, titanium, tantalum, germanium, molybdenum, ruthenium, gold, silver, platinum, palladium, and nickel. Among these, copper, tantalum, cobalt, or tungsten is preferable.

Examples of a form of the metal atom contained in the first surface include an elemental metal, an alloy, a metal nitride, a metal oxide, and a silicide.

Examples of the elemental metal include an element of a metal such as copper, iron, cobalt, tungsten, and tantalum.

Examples of the alloy include a nickel-copper alloy, a cobalt-nickel alloy, and a gold-silver alloy.

Examples of the metal nitride include tantalum nitride, titanium nitride, iron nitride, and aluminum nitride.

Examples of the metal oxide include tantalum oxide, aluminum oxide, iron oxide, and copper oxide.

Examples of the silicide include an iron silicide and a molybdenum silicide.

Among these, the first surface preferably contains an elemental metal, an alloy, a metal nitride, or a silicide, more preferably includes an elemental metal or a metal nitride, and still more preferably includes an elemental copper, an elemental cobalt, or an elemental tungsten.

The second surface is a surface not containing a metal atom, that is, a surface consisting of only non-metal atoms. The second surface usually contains an insulator.

Examples of a form of the non-metal atom contained in the second surface include an elemental non-metal, a non-metal oxide, a non-metal nitride, and a non-metal oxynitride.

Examples of the elemental non-metal include an element of silicon, carbon, or the like.

Examples of the non-metal oxide include silicon oxide and silicon oxycarbide.

Examples of the non-metal nitride include silicon nitride such as SiNₓ and Si₃N₄.

Examples of the non-metal oxynitride include SiON.

Among these, the second surface preferably contains a non-metal oxide, more preferably contains silicon, and still more preferably contains silicon oxide, silicon nitride, or silicon oxycarbide.

In the substrate, presence shapes of the first surface and the second surface are not particularly limited, and examples thereof include a surface shape, a point shape, a stripe shape, and the like in plan view. Sizes of the first surface and the second surface are not particularly limited, and can be appropriately set to a desired size region.

A shape of the substrate is not particularly limited, and can be appropriately set to a desired shape such as a plate shape.

### Heating Step

In the present step, the composition layer formed in the above-described composition layer forming step is heated.

In the present step, the bond formation between the first surface and the specific functional group in the composition is promoted, and crosslinking between the ethylenically unsaturated groups is promoted. In addition, as described above, in a case where the polymer contains the aromatic ring and the ethylenic double bond and the composition contains the thermal acid generator, the aromatic ring and the ethylenic double bond in the polymer may be crosslinked by a Friedel-Crafts reaction due to the action of the acid generated from the thermal acid generator. As a result, a coating film containing a cured substance of the polymer (crosslinked substance of the polymer) is laminated on the first surface.

The heating may be performed in one stage or in two or more stages. In a case where the heating is performed in two stages, the bond formation between the surface containing a metal atom and the specific functional group is more promoted in the first stage, and the crosslinking of the polymer is more promoted in the second stage, whereby the surface can be modified with higher density.

Examples of a heating unit include an oven and a hot plate.

A heating temperature is preferably 80° C. or higher, more preferably 100° C. or higher, still more preferably 130° C. or higher, and particularly preferably 150° C. or higher. The upper limit thereof is preferably 400° C. or lower, more preferably 300° C. or lower, still more preferably 200° C. or lower, and particularly preferably 180° C. or lower.

A heating time is preferably 10 seconds or longer, more preferably 60 seconds or longer, still more preferably 120 seconds or longer, and particularly preferably 300 seconds or longer. The upper limit thereof is preferably 120 minutes or shorter, more preferably 60 minutes or shorter, still more preferably 1,200 seconds or shorter, and particularly preferably 600 seconds or shorter.

### Removal Step

In the present step, the excess component on the substrate after the heating step is removed by a rinsing liquid.

As a result, the excess component on the substrate is removed, and a substrate in which the first surface is selectively modified is obtained.

As the rinsing liquid, an organic solvent is generally used; and examples thereof include a polyhydric alcohol partial ether carboxylate-based solvent such as propylene glycol monomethyl ether acetate and a monoalcohol-based solvent such as isopropanol.

### Contact Step

In the present step, the surface of the substrate after the above-described removal step is brought into contact with an alcohol, a dilute acid, hydrogen peroxide water, ozone, or plasma. As a result, an air-oxidized film layer formed on the second surface can be removed. Examples of the dilute acid include dilute hydrochloric acid, dilute sulfuric acid, dilute nitric acid, dilute citric acid, dilute oxalic acid, dilute maleic acid, dilute acetic acid, dilute isobutyric acid, and dilute 2-ethylhexanoic acid.

### Deposition Step

In the present step, a pattern is deposited on the surface of the substrate after the above-described removal step by a chemical vapor deposition (CVD) method or an atomic layer deposition (ALD) method. As a result, the pattern can be selectively formed on the second surface not covered with the above-described coating film.

In particular, the pattern by ALD is less likely to be formed on the region where the above-described coating film is formed, and the pattern by ALD is likely to be selectively formed on the second surface. That is, the coating film formed of the above-described composition has excellent inhibitory effect on ALD pattern formation.

### Etching Step

In the present step, the above-described polymer on the surface of the substrate after the above-described removal step is removed by etching.

Examples of the etching method include known methods including reactive ion etching (RIE) such as chemical dry etching using a difference in etching rate of each layer by using CF₄ or O₂ gas or the like and chemical wet etching (wet development) using an etchant of a liquid such as an organic solvent or hydrofluoric acid; physical etching such as sputter etching and ion beam etching; and the like. Among these, as the etching method, reactive ion etching is preferable, and chemical dry etching or chemical wet etching is more preferable.

It is optional to irradiate with radiation before the chemical dry etching. In a case where a portion to be removed by the etching is a polymer including a poly(methyl methacrylate) block, UV irradiation or the like can be used as the radiation.

In addition, an oxygen plasma treatment can also be used. Since the poly(methyl methacrylate) block is decomposed by the UV irradiation or the oxygen plasma treatment, the surface is more easily etched.

Examples of the organic solvent used for the chemical wet etching include alkanes such as n-pentane, n-hexane, and n-heptane; a cycloalkane such as cyclohexane, cycloheptane, and cyclooctane; saturated carboxylic acid esters such as ethyl acetate, n-butyl acetate, i-butyl acetate, and methyl propionate; ketones such as acetone, methyl ethyl ketone, methyl isobutyl ketone, and methyl n-pentyl ketone; and alcohols such as methanol, ethanol, 1-propanol, 2-propanol, and 4-methyl-2-pentanol. These solvents may be used alone or in combination of two or more kinds thereof.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### Materials Used for Preparation of Composition

Structures or names of each component used for the preparation of the composition of each of Examples and Comparative Examples are shown below.

### Polymer

### P-1: Polymer Synthesized by the Following Procedure

0.098 g (0.6 mmol) of azobisisobutyronitrile, 11.25 g (0.108 mol) of styrene, 0.83 g (0.002 mol) of 2-cyano-2-propyl dodecyl trithiocarbonate, 1.63 g (0.012 mol) of myrcene, and 20 g of anisole were charged into a 3-neck flask reaction container, and the mixture was heated and stirred at 80° C. for 8 hours under a nitrogen atmosphere.

The polymerization solution was purified by precipitation in 300 g of methanol, the obtained yellow viscous substance was recovered, the recovered substance was dissolved in 20 g of propylene glycol monomethyl ether acetate, 0.49 g (0.003 mol) of azobisisobutyronitrile and 2.03 g (0.010 mol) of tert-dodecanethiol were added thereto, and the mixture was refluxed at 80° C. for 2 hours to carry out a thiocarbonate terminal cleavage reaction.

The obtained polymerization solution was concentrated under reduced pressure, and purified by precipitation in 1,000 g of methanol to obtain a light yellow viscous substance. Next, the viscous substance was dried under reduced pressure at 60° C. to obtain 6.5 g of a polymer (P-1) which was a light yellow solid.

In the polymer (P-1), Mw was 4,500, Mn was 4,000, and Mw/Mn was 1.13. The specific functional group in the polymer (P-1) was a cyano group, and the ethylenically unsaturated group (group selected from the group consisting of an alkenyl group having 2 to 4 carbon atoms and an alkenylene group having 2 to 4 carbon atoms) was contained in a unit derived from the myrcene.

### P-2: Polymer Synthesized by the Following Procedure

0.098 g (0.6 mmol) of azobisisobutyronitrile, 10.63 g (0.102 mol) of styrene, 0.58 g (0.002 mol) of dibenzyl trithiocarbonate, 1.63 g (0.012 mol) of myrcene, and 20 g of anisole were charged into a 3-neck flask reaction container, and the mixture was heated and stirred at 80° C. for 5 hours under a nitrogen atmosphere.

Next, 0.64 g (0.006 mol) of vinylphosphoric acid was added thereto, and the mixture was heated and stirred at 80° C. for 3 hours.

The polymerization solution was purified by precipitation in 300 g of methanol, the obtained yellow viscous substance was recovered, the recovered substance was dissolved in 20 g of propylene glycol monomethyl ether acetate, 0.49 g (0.003 mol) of azobisisobutyronitrile and 2.03 g (0.010 mol) of tert-dodecanethiol were added thereto, and the mixture was refluxed at 80° C. for 2 hours to carry out a thiocarbonate terminal cleavage reaction.

The obtained polymerization solution was concentrated under reduced pressure, and purified by precipitation in 1,000 g of methanol to obtain a light yellow viscous substance. Next, the viscous substance was dried under reduced pressure at 60° C. to obtain 6.5 g of a polymer (P-2) which was a light yellow solid.

In the polymer (P-2), Mw was 4,600, Mn was 3,800, and Mw/Mn was 1.21. The specific functional group in the polymer (P-2) was a phosphoric acid group, and the ethylenically unsaturated group (group selected from the group consisting of an alkenyl group having 2 to 4 carbon atoms and an alkenylene group having 2 to 4 carbon atoms) was contained in a unit derived from the myrcene.

### P-3: Polymer Synthesized by the Following Procedure

The 3-neck flask reaction container was dried under reduced pressure, and 120 g of THF subjected to a distillation dehydration treatment under a nitrogen atmosphere was injected thereto and cooled to −78° C. 2.09 mL (2.03 mmol) of a 1 N cyclohexane solution of sec-butyllithium (sec-BuLi) was injected into the THF, and then 11.1 mL (0.062 mol) of styrene and 0.78 mL (5.38 mmol) of 4-allylstyrene, which had been subjected to adsorption filtration with silica gel for removing a polymerization inhibitor and distillation dehydration treatment, were further added dropwise thereto over 30 minutes, and it was confirmed that the polymerization system was orange. During the dropwise addition, care was taken that an internal temperature of the reaction solution did not reach-60° C. or higher.

0.34 mL (2.03 mmol) of bromopropionitrile as a terminating agent and 4.1 mL (2.03 mmol) of a 0.5 N tetrahydrofuran solution of lithium chloride were added thereto to carry out a termination reaction of polymerization terminals. The reaction solution was heated to room temperature, and the obtained reaction solution was concentrated to substitute the solvent with MIBK.

Thereafter, 1,000 g of a 2% by mass aqueous solution of oxalic acid was injected thereto and stirred, and after standing, the lower phase as aqueous phase was removed. This operation was repeated three times to remove the Li salt. Thereafter, 1,000 g of ultrapure water was injected thereto and stirred, and the lower phase as aqueous phase was removed.

This operation was repeated three times to remove the oxalic acid, and then the solution was concentrated and added dropwise to 500 g of methanol to precipitate the polymer, and the solid was recovered by Buchner funnel. The solid was dried under reduced pressure at 60° C. to obtain 10.5 g of a white polymer (P-3).

In the polymer (P-3), Mw was 5,300, Mn was 5,100, and Mw/Mn was 1.04. The specific functional group in the polymer (P-3) was a cyano group, and the ethylenically unsaturated group (group selected from the group consisting of an alkenyl group having 2 to 4 carbon atoms and an alkenylene group having 2 to 4 carbon atoms) was contained in a unit derived from the 4-allylstyrene.

### Thermal Acid Generator

A-1: diphenyliodonium nonafluorobutane-1-sulfonate (acid generation temperature=170° C.)

### Polymerization Inhibitor

I-1: 4-methoxyphenol (phenol-based compound)
I-2: N-nitroso-N-phenylhydroxylamine aluminum (amine-based compound)
I-3: poly(4-methacryloyloxy-2,2,6,6-tetramethylpiperidine-N-oxyl) (free radical-based compound)
I-4: 4-tert-butylcatechol (phenol-based compound)
I-5: 1,4-benzoquinone (quinone-based compound)
I-6: phenothiazine (amine-based compound)
I-7: N,N-diethylhydroxylamine (amine-based compound)
I-8: 4-hydroxy-2,2,6,6-tetramethylpiperidine 1-oxyl (free radical-based compound)
I-9: cupferron (amine-based compound)
I-10: 2,2-diphenyl-1-picrylhydrazyl (free radical-based compound)
I-11: triphenylverdazyl (free radical-based compound)
I-12: pentaerythritol tetrakis[3-(3,5-di-tert-butyl-4-hydroxyphenyl)propionate](phenol-based compound)
I-13: 2,2,6,6-tetramethylpiperidine 1-oxyl (free radical-based compound)
I-14: tris(2,4-di-tert-butylphenyl) phosphite (phosphine-based compound)
I-15: dioctadecyl 3,3′-thiodipropionate (thiol ether-based compound)
I-16: 2,4-bis(octylthiomethyl)-6-methylphenol (phenol-based compound)

### Solvent

S-1: propylene glycol monomethyl ether acetate (PGMEA)
S-2: ethyl lactate

### Method for Preparing Composition

A method for preparing a composition of Example 1 will be described below.

0.05 g of the thermal acid generator (A-1), 0.02 g of the polymerization inhibitor (I-1), 74.03 g of the solvent (S-1), and 24.67 g of the solvent (S-2) were added to 1.25 g of the polymer (P-1), and the mixture was stirred and then filtered through a high-density polyethylene filter having a fine pore of 0.45 μm to prepare a composition.

In addition, compositions of each of Examples and Comparative Examples were prepared in the same manner as in Example 1, except that each of the components with the types and the blending amounts shown in the tables later was used.

### Modification of Substrate Surface

The substrate surface was modified using the composition of each of Examples and Comparative Examples according to the following procedure.

A copper (Cu) substrate was immersed in a 1% by mass aqueous solution of citric acid, and then dried with a nitrogen flow to remove an oxide coating film on the surface. A silicon oxide (SiO₂) substrate was subjected to a surface treatment with isopropanol.

Next, the Cu substrate and the SiO₂ substrate after the above-described surface treatment was spin-coated with the composition prepared as described above at 1,500 rpm, and the coated substrates were heated at 150° C. for 180 seconds. The substrate was washed with PGMEA.

### Evaluation Method

Using the substrate produced by the above-described procedure, storage stability of the composition and selectivity of the surface modification were evaluated.

### Contact Angle

A water contact angle of the substrate surface produced by the above-described procedure was measured using a contact angle meter (Drop master DM-503, manufactured by Kyowa Interface Science Co., Ltd.). The evaluation was carried out within 24 hours from the preparation of the composition.

### Evaluation of Storage Stability

Using the composition of each of Examples and Comparative Examples, stored at 45° C. for 1 month, the substrate was modified in the same manner as described in [Modification of substrate surface] above. A water contact angle of the substrate surface was measured by the procedure described in <Contact angle> above, and the obtained value was evaluated for storage stability in accordance with the following standard.

### Evaluation Standard

A: water contact angle was 50° or less.
B: water contact angle was more than 50° and less than 60°.
C: water contact angle was 60° or more.

### Evaluation of Selective Surface Modification on Stripe Substrate Consisting of Copper-Silicon Oxide

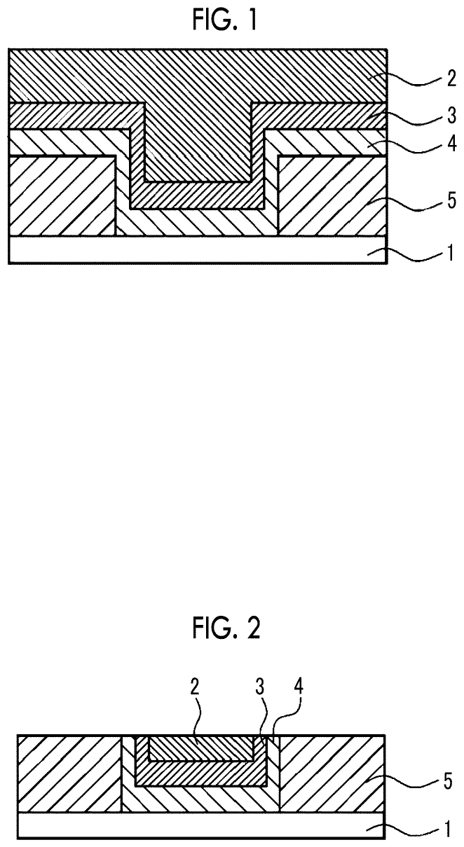

An 8-inch substrate (Cu-EPC: 10,000 Å/Cu-Seed: 1,000 Å/TaN Barrier Layer: 250 Å/silicon oxide: 5,000 Å/silicon wafer, 0.18 μm trench) shown in FIG. 1 was polished with a CMP slurry to produce a substrate in which copper (Cu) and silicon oxide (SiO₂) were arranged in a stripe shape as shown in FIG. 2. Next, the substrate was immersed in a 5% by mass aqueous solution of oxalic acid, and then dried with a nitrogen flow to remove the oxide coating film on the surface.

The substrate shown in FIG. 1 included a silicon wafer 1, a Cu-EPC 2, a Cu-seed 3, a tantalum nitride (TaN) 4, and a silicon oxide 5.

The substrate was spin-coated with the composition in <Evaluation of storage stability> described above, stored at 45° C. for 1 month, at 1,500 rpm using a track (ACT8, manufactured by Tokyo Electron Limited), and heated at 150° C. for 180 seconds.

The substrate was washed with PGMEA. Next, the surface was observed with a scanning probe microscope (Dimension iCON, manufactured by Bruker), and a film thickness of the coating portion was calculated from unevenness.

An average thickness (Å) of the coating film formed on each region of copper and silicon oxide on the copper-silicon oxide stripe substrate is shown in the tables. “ND” in the tables indicates that the thickness was small and thus could not be detected.

The region of copper and tantalum nitride on the copper-silicon oxide stripe substrate was the surface containing a metal atom, and the region of silicon oxide corresponds to the surface not containing a metal atom.

### Result

The evaluation results are shown in the tables. In the tables, Comparative Example 2 shows a result of a blank in which the substrate surface was not treated with the composition.

TABLE 1

| | | | Example | Example | Example | Example | Example |
|---|---|---|---|---|---|---|---|
| Table 1(1) | | | 1 | 2 | 3 | 4 | 5 |
| Composition | Polymer | P-1 | 1.25 | 1.25 | 1.25 | 1.25 | 1.25 |
| | | P-2 | — | — | — | — | — |
| | | P-3 | — | — | — | — | — |
| | Thermal acid | A-1 | 0.05 | 0.05 | 0.05 | 0.05 | 0.05 |
| | generator | | | | | | |
| | Polymerization | I-1 | 0.02 | — | — | — | — |
| | inhibitor | I-2 | — | 0.02 | — | — | — |
| | | I-3 | — | — | 0.02 | — | — |
| | | I-4 | — | — | — | 0.02 | — |
| | | I-5 | — | — | — | — | 0.02 |
| | | I-6 | — | — | — | — | — |
| | | I-7 | — | — | — | — | — |
| | | I-8 | — | — | — | — | — |
| | | I-9 | — | — | — | — | — |
| | | I-10 | — | — | — | — | — |
| | | I-11 | — | — | — | — | — |
| | | I-12 | — | — | — | — | — |
| | | I-13 | — | — | — | — | — |
| | | I-14 | — | — | — | — | — |
| | | I-15 | — | — | — | — | — |
| | | I-16 | — | — | — | — | — |
| | Solvent | S-1 | 74.03 | 74.03 | 74.03 | 74.03 | 74.03 |
| | | S-2 | 24.67 | 24.67 | 24.67 | 24.67 | 24.67 |
| | Total (g) | | 100.02 | 100.02 | 100.02 | 100.02 | 100.02 |
| Evaluation | Storage stability | Before | 86 | 86 | 86 | 86 | 86 |
| | (contact angle (°)) | evaluation: Cu | | | | | |
| | | After | 86 | 86 | 86 | 86 | 86 |
| | | evaluation: Cu | | | | | |
| | | Before | 41 | 41 | 41 | 41 | 41 |
| | | evaluation: SiO₂ | | | | | |
| | | After | 41 | 51 | 49 | 50 | 41 |
| | | evaluation: SiO₂ | A | B | A | A | A |
| | Evaluation of | Thickness of | — | — | — | — | — |
| | selective surface | polymer coating film | | | | | |
| | modification on | on Cu and TaN (Å) | | | | | |
| | stripe substrate | Thickness of | — | — | — | — | — |
| | | polymer coating | | | | | |
| | | film on SiO₂ (Å) | | | | | |
| | | | Example | Example | Example | Example | Example |
| Table 1(1) | | | 6 | 7 | 8 | 9 | 10 |
| Composition | Polymer | P-1 | 1.25 | 1.25 | 1.25 | 1.25 | 1.25 |
| | | P-2 | — | — | — | — | — |
| | | P-3 | — | — | — | — | — |
| | Thermal acid | A-1 | 0.05 | 0.05 | 0.05 | 0.05 | 0.05 |
| | generator | | | | | | |
| | Polymerization | I-1 | — | — | — | — | — |
| | inhibitor | I-2 | — | — | — | — | — |
| | | I-3 | — | — | — | — | — |
| | | I-4 | — | — | — | — | — |
| | | I-5 | — | — | — | — | — |
| | | I-6 | 0.02 | — | — | — | — |
| | | I-7 | — | 0.02 | — | — | — |
| | | I-8 | — | — | 0.02 | — | — |
| | | I-9 | — | — | — | 0.02 | — |
| | | I-10 | — | — | — | — | 0.02 |
| | | I-11 | — | — | — | — | — |
| | | I-12 | — | — | — | — | — |
| | | I-13 | — | — | — | — | — |
| | | I-14 | — | — | — | — | — |
| | | I-15 | — | — | — | — | — |
| | | I-16 | — | — | — | — | — |
| | Solvent | S-1 | 74.03 | 74.03 | 74.03 | 74.03 | 74.03 |
| | | S-2 | 24.67 | 24.67 | 24.67 | 24.67 | 24.67 |
| | Total (g) | | 100.02 | 100.02 | 100.02 | 100.02 | 100.02 |
| Evaluation | Storage stability | Before | 86 | 86 | 86 | 86 | 86 |
| | (contact angle (°)) | evaluation: Cu | | | | | |
| | | After | 86 | 86 | 86 | 86 | 86 |
| | | evaluation: Cu | | | | | |
| | | Before | 41 | 41 | 41 | 41 | 41 |
| | | evaluation: SiO₂ | | | | | |
| | | After | 52 | 51 | 41 | 51 | 48 |
| | | evaluation: SiO₂ | B | B | A | B | A |
| | Evaluation of | Thickness of | — | — | 50.1 | — | — |
| | selective surface | polymer coating film | | | | | |
| | modification on | on Cu and TaN (Å) | | | | | |
| | stripe substrate | Thickness of | — | — | ND | — | — |
| | | polymer coating | | | | | |
| | | film on SiO₂ (Å) | | | | | |

TABLE 2

| | | | Example | Example | Example | Example | Example |
|---|---|---|---|---|---|---|---|
| Table 1(2) | | | 11 | 12 | 13 | 14 | 15 |
| Composition | Polymer | P-1 | 1.25 | 1.25 | 1.25 | 1.25 | 1.25 |
| | | P-2 | — | — | — | — | — |
| | | P-3 | — | — | — | — | — |
| | Thermal acid | A-1 | 0.05 | 0.05 | 0.05 | 0.05 | 0.05 |
| | generator | | | | | | |
| | Polymerization | I-1 | — | — | — | — | — |
| | inhibitor | I-2 | — | — | — | — | — |
| | | I-3 | — | — | — | — | — |
| | | I-4 | — | — | — | — | — |
| | | I-5 | — | — | — | — | — |
| | | I-6 | — | — | — | — | — |
| | | I-7 | — | — | — | — | — |
| | | I-8 | — | — | — | — | — |
| | | I-9 | — | — | — | — | — |
| | | I-10 | — | — | — | — | — |
| | | I-11 | 0.02 | — | — | — | — |
| | | I-12 | — | 0.02 | — | — | — |
| | | I-13 | — | — | 0.02 | — | — |
| | | I-14 | — | — | — | 0.02 | — |
| | | I-15 | — | — | — | — | 0.02 |
| | | I-16 | — | — | — | — | — |
| | Solvent | S-1 | 74.03 | 74.03 | 74.03 | 74.03 | 74.03 |
| | | S-2 | 24.67 | 24.67 | 24.67 | 24.67 | 24.67 |
| | Total (g) | | 100.02 | 100.02 | 100.02 | 100.02 | 100.02 |
| Evaluation | Storage stability | Before | 86 | 86 | 86 | 86 | 86 |
| | (contact angle (°)) | evaluation: Cu | | | | | |
| | | After | 86 | 86 | 86 | 86 | 86 |
| | | evaluation: Cu | | | | | |
| | | Before | 41 | 41 | 41 | 41 | 41 |
| | | evaluation: SiO₂ | | | | | |
| | | After | 48 | 42 | 41 | 52 | 52 |
| | | evaluation: SiO₂ | A | A | A | B | B |
| | Evaluation of | Thickness of | — | — | 49.9 | — | — |
| | selective surface | polymer coating film | | | | | |
| | modification on | on Cu and TaN (Å) | | | | | |
| | stripe substrate | Thickness of | — | — | ND | — | — |
| | | polymer coating | | | | | |
| | | film on SiO₂ (Å) | | | | | |
| | | | Example | Example | Example | Example | Example |
| Table 1(2) | | | 16 | 17 | 18 | 19 | 20 |
| Composition | Polymer | P-1 | 1.25 | — | — | | |
| | | P-2 | — | 1.25 | 1.25 | 1.25 | 1.25 |
| | | P-3 | — | — | — | | |
| | Thermal acid | A-1 | 0.05 | 0.05 | 0.05 | 0.05 | 0.05 |
| | generator | | | | | | |
| | Polymerization | I-1 | — | 0.02 | — | — | — |
| | inhibitor | I-2 | — | — | — | — | — |
| | | I-3 | — | — | — | — | — |
| | | I-4 | — | — | — | — | — |
| | | I-5 | — | — | 0.02 | — | — |
| | | I-6 | — | — | — | — | — |
| | | I-7 | — | — | — | — | — |
| | | I-8 | — | — | — | 0.02 | |
| | | I-9 | — | — | — | | |
| | | I-10 | — | — | — | | |
| | | I-11 | — | — | — | | |
| | | I-12 | — | — | — | | |
| | | I-13 | — | — | — | | 0.02 |
| | | I-14 | — | — | — | | |
| | | I-15 | — | — | — | | |
| | | I-16 | 0.02 | — | — | | |
| | Solvent | S-1 | 74.03 | 74.03 | 74.03 | 74.03 | 74.03 |
| | | S-2 | 24.67 | 24.67 | 24.67 | 24.67 | 24.67 |
| | Total (g) | | 100.02 | 100.02 | 100.02 | 100.02 | 100.02 |
| Evaluation | Storage stability | Before | 86 | 86 | 86 | 90 | 90 |
| | (contact angle (°)) | evaluation: Cu | | | | | |
| | | After | 86 | 86 | 86 | 90 | 90 |
| | | evaluation: Cu | | | | | |
| | | Before | 41 | 38 | 38 | 37 | 37 |
| | | evaluation: SiO₂ | | | | | |
| | | After | 42 | 38 | 38 | 37 | 37 |
| | | evaluation: SiO₂ | A | A | A | A | A |
| | Evaluation of | Thickness of | — | — | — | — | — |
| | selective surface | polymer coating film | | | | | |
| | modification on | on Cu and TaN (Å) | | | | | |
| | stripe substrate | Thickness of | — | — | — | — | — |
| | | polymer coating | | | | | |
| | | film on SiO₂ (Å) | | | | | |

TABLE 3

| | | | Example | Example | Example | Example | Example | Example | Example |
|---|---|---|---|---|---|---|---|---|---|
| Table 1(3) | | | 21 | 22 | 23 | 24 | 25 | 26 | 27 |
| Composition | Polymer | P-1 | — | — | — | — | 10 | 0.01 | 1.25 |
| | | P-2 | — | — | — | — | — | — | — |
| | | P-3 | 1.25 | 1.25 | 1.25 | 1.25 | — | — | — |
| | Thermal acid | A-1 | 0.05 | 0.05 | 0.05 | 0.05 | 0.05 | — | 5 |
| | generator | | | | | | | | |
| | Polymerization | I-1 | 0.02 | — | — | — | — | — | — |
| | inhibitor | I-2 | — | — | — | — | — | — | — |
| | | I-3 | — | — | — | — | — | — | — |
| | | I-4 | — | — | — | — | — | — | — |
| | | I-5 | — | 0.02 | — | — | — | — | — |
| | | I-6 | — | — | — | — | — | — | — |
| | | I-7 | — | — | — | — | — | — | — |
| | | I-8 | — | — | 0.02 | — | 0.02 | 0.02 | 0.02 |
| | | I-9 | — | — | — | — | — | — | — |
| | | I-10 | — | — | — | — | — | — | — |
| | | I-11 | — | — | — | — | — | — | — |
| | | I-12 | — | — | — | — | — | — | — |
| | | I-13 | — | — | — | 0.02 | — | — | — |
| | | I-14 | — | — | — | — | — | — | — |
| | | I-15 | — | — | — | — | — | — | — |
| | | I-16 | — | — | — | — | — | — | — |
| | Solvent | S-1 | 74.03 | 74.03 | 74.03 | 74.03 | 74.03 | 74.03 | 74.03 |
| | | S-2 | 24.67 | 24.67 | 24.67 | 24.67 | 24.67 | 74.67 | 24.67 |
| | Total (g) | | 100.02 | 100.02 | 100.02 | 100.02 | 108.77 | 98.73 | 104.97 |
| Evaluation | Storage stability | Before | 85 | 85 | 85 | 85 | 86 | 86 | 86 |
| | (contact angle (°)) | evaluation: Cu | | | | | | | |
| | | After | 85 | 85 | 85 | 85 | 86 | 86 | 86 |
| | | evaluation: Cu | | | | | | | |
| | | Before | 37 | 37 | 37 | 37 | 41 | 41 | 41 |
| | | evaluation: SiO₂ | | | | | | | |
| | | After | 37 | 37 | 37 | 37 | 41 | 41 | 41 |
| | | evaluation: SiO₂ | A | A | A | A | A | A | A |
| | Evaluation of | Thickness of | — | — | — | — | — | — | — |
| | selective surface | polymer coating film | | | | | | | |
| | modification on | on Cu and TaN (Å) | | | | | | | |
| | stripe substrate | Thickness of | — | — | — | — | — | — | — |
| | | polymer coating | | | | | | | |
| | | film on SiO₂ (Å) | | | | | | | |

| | | | | | | | Compar- | Compar- |
|---|---|---|---|---|---|---|---|---|
| | | | Example | Example | Example | Example | ative | ative |
| Table 1(3) | | | 28 | 29 | 30 | 31 | Example 1 | Example 2 |
| Composition | Polymer | P-1 | 1.25 | 1.25 | 1.25 | 0.6 | — | — |
| | | P-2 | — | — | — | 0.6 | — | — |
| | | P-3 | — | — | — | — | 1.2 | — |
| | Thermal acid | A-1 | 0.01 | 0.05 | 0.05 | 0.05 | — | — |
| | generator | | | | | | | |
| | Polymerization | I-1 | — | — | — | — | — | — |
| | inhibitor | I-2 | — | — | — | — | — | — |
| | | I-3 | — | — | — | — | — | — |
| | | I-4 | — | — | — | — | — | — |
| | | I-5 | — | — | — | — | — | — |
| | | I-6 | — | — | — | — | — | — |
| | | I-7 | — | — | — | — | — | — |
| | | I-8 | 0.02 | 0.001 | 1 | 0.02 | — | — |
| | | I-9 | — | — | — | — | — | — |
| | | I-10 | — | — | — | — | — | — |
| | | I-11 | — | — | — | — | — | — |
| | | I-12 | — | — | — | — | — | — |
| | | I-13 | — | — | — | — | — | — |
| | | I-14 | — | — | — | — | — | — |
| | | I-15 | — | — | — | — | — | — |
| | | I-16 | — | — | — | — | — | — |
| | Solvent | S-1 | 74.03 | 74.03 | 74.03 | 74.03 | 98.8 | — |
| | | S-2 | 24.67 | 24.67 | 24.67 | 24.67 | — | — |
| | Total (g) | | 99.98 | 100.001 | 101 | 99.97 | 100 | — |
| Evaluation | Storage stability | Before | 86 | 86 | 86 | 86 | 85 | 64 |
| | (contact angle (°)) | evaluation: Cu | | | | | | |
| | | After | 86 | 86 | 86 | 86 | 87 | — |
| | | evaluation: Cu | | | | | | |
| | | Before | 41 | 41 | 41 | 39 | 37 | 36 |
| | | evaluation: SiO₂ | | | | | | |
| | | After | 41 | 41 | 41 | 39 | 60 | — |
| | | evaluation: SiO₂ | A | A | A | A | C | — |
| | Evaluation of | Thickness of | — | — | — | — | — | — |
| | selective surface | polymer coating film | | | | | | |
| | modification on | on Cu and TaN (Å) | | | | | | |
| | stripe substrate | Thickness of | — | — | — | — | — | — |
| | | polymer coating | | | | | | |
| | | film on SiO₂ (Å) | | | | | | |

As shown in the tables, it was found that the composition according to the embodiment of the present invention in each of Examples exhibited a desired effect.

On the other hand, in Comparative Examples, since the composition did not contain the polymerization inhibitor, it was found that the storage stability of the composition was deteriorated, and the silicon oxide was also modified with the polymer, and thus the substrate surface could not be selectively modified.

In addition, from the comparison of Examples 1 to 16, it was found that, in a case where the polymerization inhibitor contained in the composition was a phenol-based compound, a quinone-based compound, or a free radical-based compound, the effect of the present invention was more excellent.

From the comparison of Example 8 and Example 19, the comparison of Example 13 and Example 20, and the like, it was found that, in a case where the polymerization inhibitor contained in the composition contained a nitrogen atom and the polymer had the specific functional group such as a phosphoric acid group or a salt thereof, the numerical value of the contact angle of the modified copper substrate was relatively large, and the polymer was more likely to be deposited on the surface containing a metal atom such as copper, and thus the selectivity of the polymer to the surface containing a metal atom with respect to the surface not containing a metal atom was improved.

### EXPLANATION OF REFERENCES

1: silicon wafer
2: Cu-EPC
3: Cu-seed
4: TaN
5: silicon oxide

What is claimed is:

1. A composition for treating a semiconductor device, comprising:
a polymer having a functional group which interacts with a surface containing a metal atom in a substrate and an ethylenically unsaturated group;
a polymerization inhibitor; and
a solvent.

2. The composition for treating a semiconductor device according to claim 1,
wherein the functional group is a group selected from the group consisting of a nitrogen-containing group, a phosphoric acid group or a salt thereof, a carboxy group or a salt thereof, a hydroxy group, an epoxy group, a hydrolyzable silyl group, a thiol group, and a disulfide group.

3. The composition for treating a semiconductor device according to claim 1,
wherein the functional group is a cyano group, or a phosphoric acid group or a salt thereof.

4. The composition for treating a semiconductor device according to claim 1,
wherein the ethylenically unsaturated group is a group selected from the group consisting of a vinyl group, a vinyl ether group, a styryl group, an acryloyl group, and a methacryloyl group.

5. The composition for treating a semiconductor device according to claim 1,
wherein the ethylenically unsaturated group is a group selected from the group consisting of an alkenyl group having 2 to 4 carbon atoms and an alkenylene group having 2 to 4 carbon atoms.

6. The composition for treating a semiconductor device according to claim 1,
wherein the polymer includes a ring structure.

7. The composition for treating a semiconductor device according to claim 6,
wherein the polymer includes an aromatic ring structure.

8. The composition for treating a semiconductor device according to claim 1,
wherein the polymerization inhibitor contains a nitrogen atom.

9. The composition for treating a semiconductor device according to claim 1,
wherein the polymerization inhibitor includes at least one compound selected from the group consisting of a phenol-based compound, a quinone-based compound, a free radical-based compound, an amine-based compound, a phosphine-based compound, and a thiol ether-based compound.

10. The composition for treating a semiconductor device according to claim 9,
wherein the polymerization inhibitor is a phenol-based compound, a quinone-based compound, or a free radical-based compound.

11. The composition for treating a semiconductor device according to claim 1,
wherein a content of the polymerization inhibitor is 0.08 to 200 parts by mass with respect to 100 parts by mass of the polymer.

12. The composition for treating a semiconductor device according to claim 1,
wherein the solvent includes at least one solvent selected from the group consisting of an ester-based solvent, a ketone-based solvent, and an alcohol-based solvent.

13. The composition for treating a semiconductor device according to claim 12,
wherein the solvent includes at least one solvent selected from the group consisting of propylene glycol monomethyl ether acetate, ethyl lactate, γ-butyrolactone, cyclohexanone, methyl isobutyl ketone, and propylene glycol monomethyl ether.

14. A method for manufacturing a modified substrate, comprising:
a step of bringing a substrate having a first surface containing a metal atom and a second surface not containing a metal atom into contact with the composition for treating a semiconductor device according to claim 1; and
a step of subjecting the substrate brought into contact with the composition to a heating treatment to form a coating film on the first surface.

15. The method for manufacturing a modified substrate according to claim 14,
wherein the second surface contains an insulator.

16. The method for manufacturing a modified substrate according to claim 14,
wherein the second surface contains silicon.

17. The method for manufacturing a modified substrate according to claim 14,
wherein the second surface contains silicon oxide, silicon nitride, or silicon oxycarbide.

18. The composition for treating a semiconductor device according to claim 2,
wherein the functional group is a cyano group, or a phosphoric acid group or a salt thereof.

19. The composition for treating a semiconductor device according to claim 2,
wherein the ethylenically unsaturated group is a group selected from the group consisting of a vinyl group, a vinyl ether group, a styryl group, an acryloyl group, and a methacryloyl group.

20. The composition for treating a semiconductor device according to claim 2,
wherein the ethylenically unsaturated group is a group selected from the group consisting of an alkenyl group having 2 to 4 carbon atoms and an alkenylene group having 2 to 4 carbon atoms.
